(19) United States
(12) Patent Application Publication
(10) Pub. No.: US 2026/0280485 A1
(43) Pub. Date: Sep. 17, 2026

(54) PHOTOVOLTAIC (PV) PANEL SIMULATION SYSTEM AND MEASUREMENT TOOL CALIBRATION

(71) Applicant: Fluke Corporation, Everett, WA (US)

(72) Inventors: Alex J. Cimaroli, Everett, WA (US); Patrick O. Hall, Everett, WA (US); Ricardo R. Rodriguez, Everett, WA (US)

(21) Appl. No.: 19/480,122

(22) PCT Filed: May 2, 2024
(86) PCT No.: PCT/US2024/027381

§ 371 Date: Oct. 30, 2025

Related U.S. Application Data
(60) Provisional application No. 63/500,217, filed on May 4, 2023.

(51) Int. Cl. H02S 50/10; G01R 35/00

(52) U.S. Cl. CPC H02S 50/10; G01R 35/005

(57) ABSTRACT

A photovoltaic (PV) panel simulator includes a high-side linear current source and an output circuit. The high-side linear current source includes a voltage source and a feedback loop in which an operational amplifier controls the generation of source current in response to a reference signal received from a controller and a feedback signal received via the feedback loop. The output circuit produces an output current, and includes one or more components with configurable electrical parameters which, in combination, simulate electrical characteristics of a PV panel. In response to connection of a load of an IV curve tracer, the PV panel simulator produces an output current produced at a magnitude that settles from an initial state to approximately a steady state within a settling time period. The settling time period precedes a measurement time period during which the IV curve tracer measures the output current and voltage in the steady state.

### BACKGROUND

### Technical Field

The present disclosure pertains to systems that simulate a photovoltaic (PV) panel for testing and calibrating electrical measurement tools such as current-voltage (IV) curve tracers that are used to test and evaluate PV panels.

### Description of the Related Art

A photovoltaic (PV) cell, also known as a solar cell, is a device that converts light energy into electricity. A PV panel (or solar panel) includes one or more PV cells. PV panels can vary in size and capacity for electricity production. Typical solar panels include an array of PV cells that are connected to provide a combined electrical output.

Photovoltaic (PV) analyzers are electrical measurement tools that are used to test the performance and efficiency of PV panels under different conditions. One type of test measures the current and voltage of electrical output from a PV panel under different environmental conditions, such as different light irradiance and temperature. This type of test generates an “IV curve.” An IV curve is comprised of a number of current (I) and voltage (V) measurements that are assembled into a graph. Electrical power is determined as a function of the measured current and voltage. IV curve tracing provides effective evaluation of the performance of a PV panel.

An IV curve tracer may be a standalone device or a functional aspect of a multifunction PV analyzer. To generate an IV curve, an IV curve tracer applies a variable load to a PV panel at different points in time, ranging from zero impedance (short circuit) to high impedance (open circuit), and measures the current and voltage across the load at each instance of time. The variable load is connected to the PV panel during a measurement pulse of short duration. The IV curve tracer then plots the current and voltage measurements to display the IV curve. By analyzing a measured IV curve, a technician can evaluate aspects of the PV panel such as the maximum power point (MPP), fill factor (FF), short circuit current (Isc), and open circuit voltage (Voc). A measured IV curve can also be used to identify problems or defects in the PV panel by comparing the measured IV curve with an expected IV curve based on specifications of the PV panel.

Thus, an IV curve is useful to validate the operation of a PV panel. IV curve tracing may be conducted during manufacturing, installation, and/or operation of the PV panel. Regular testing of PV panels with IV curve tracing helps a PV panel operator ensure ongoing, reliable power generation.

IV curve tracers themselves should be tested and calibrated from time to time to ensure their proper operation. There ips an unmet need, however, for a system that can realistically and accurately simulate a PV panel that can be used to conveniently test and calibrate field-capable IV curve tracers. Currently-available solar simulators operate at too low power and/or cannot effectively test and calibrate field-capable IV curve tracers.

A PV panel simulation system is needed which produces an electrical output similar to a PV panel, which quickly responds to measurement loads presented by an IV curve tracer in short measurement pulses. A quick response is determined, at least in part, by the time required for the current and voltage across the measurement load to settle to approximately a steady state output current and voltage. What is also needed is a PV panel simulation system having configurable parameters that enable the system to simulate different PV panels under different environmental and load conditions.

### BRIEF SUMMARY

Disclosed herein is a PV panel simulation system comprised of a high-side linear current source and an output circuit that simulates electrical characteristics of a photovoltaic (PV) panel. The high-side linear current source is comprised of a voltage source and a feedback loop that quickly respond to measurement loads, ranging from a short circuit to open circuit, that are connected to the PV panel simulation system in short measurement pulses.

The output circuit is configured to receive a source current from the high-side linear current source and produce an output current that is delivered to a measurement load connected to the PV panel simulation system. The output circuit includes one or more electrical components with configurable parameters that, in combination, simulate electrical characteristics of a PV panel.

In response to connection of a load to the PV panel simulation system, e.g., by an IV curve tracer, the PV panel simulation system produces the output current at a magnitude that settles from an initial state to approximately a steady state within a settling time period. This settling time period precedes a measurement time period in which the IV curve tracer measures the magnitude of the current and voltage across the load in the steady state.

By producing a carefully-sourced output current that has quickly settled before each measurement is made by an IV curve tracer, the PV panel simulation system ensures that the IV curve measured by the IV curve tracer represents the current operating condition of the IV curve tracer. External calibration equipment (or possibly the PV panel simulation system) can then compare the IV curve tracer's measured IV curve with an expected IV curve based on specifications of the PV panel being simulated, and determine any calibration corrections that may be need to be applied to the IV curve tracer to ensure proper operation of the IV curve tracer.

### BRIEF DESCRIPTION OF THE SEVERAL VIEWS OF THE DRAWINGS

FIG. 1 is a graph that illustrates an example IV curve measured by an IV curve tracer connected to a photovoltaic (PV) panel.

FIG. 2 is a circuit diagram that illustrates a lumped circuit model of a PV panel simulator according to the present disclosure, connected to a load of an IV curve tracer.

FIG. 3 is a timing diagram illustrating the output of a PV panel simulator according to the present disclosure, operating in response to a measurement pulse of an IV curve tracer.

FIG. 4 is a circuit diagram illustrating one example of a PV panel simulator according to the present disclosure, connected to a load of an IV curve tracer.

### DETAILED DESCRIPTION

The present disclosure addresses a need for a photovoltaic (PV) panel simulation system that can produce an electrical output similar to a PV panel, wherein the electrical output quickly responds to measurement loads presented in short measurement pulses by a measurement tool, such as an IV curve tracer. The present disclosure also addresses a need for a PV panel simulation system having components with configurable parameters that enable a user to adjust the PV simulator so as to simulate different PV panels under different environmental and load conditions.

A PV panel simulation system as disclosed herein, also referred to herein as a PV panel simulator, produces an output current that settles to approximately a steady state before a measurement is made by an IV curve tracer. In this manner, the PV panel simulator ensures that an IV curve measured by the IV curve tracer represents a true measurement by the IV curve tracer.

Calibration of the IV curve tracer, if needed, can then be accomplished by taking the measured IV curve measured by IV curve tracer and comparing it with an expected IV curve based on specifications of the PV panel being simulated. Based on detected differences, if any, between the measured IV curve and the expected IV curve, external calibration equipment (or possibly the PV panel simulator) can determine a calibration correction that, when applied to the IV curve tracer, ensures proper operation of the IV curve tracer.

In at least one implementation, a PV panel simulation system (or “PV panel simulator”) as described herein includes a high-side linear current source and an output circuit that simulates electrical characteristics of a PV panel. The high-side linear current source includes a voltage source and a feedback loop that enable the PV panel simulator to quickly respond to measurement loads presented by an IV curve tracer. The measurement loads are connected to the PV panel simulator in short measurement pulses.

In at least one implementation, the feedback loop of the PV panel simulator includes an operational amplifier and a current sense resistor. The operational amplifier controls the source current generated by the high-side linear current source in response to a reference signal and a feedback voltage. The reference signal is received from a controller using, for example, a digital-to-analog converter (DAC), and the feedback voltage is received from the current sense resistor in the feedback loop. In this manner, the high-side linear current source is configured to generate a desired source current and is able to react quickly to different loads presented by an IV curve tracer. The reference signal from the controller controls the generation of different magnitudes of source current by the high-side linear current source in order to simulate a PV panel under different environmental conditions.

The output circuit of the PV panel simulator receives the source current generated by the high-side linear current source and produces an output current that is delivered to the measurement load presented by the IV curve tracer. In at least one implementation, the output circuit includes one or more electrical components having configurable parameters that simulate known electrical characteristics of a PV panel. In this manner, a user is able to configure the components of the output circuit so that the PV panel simulator simulates electrical characteristics of different PV panels.

In response to connection of a load, e.g., by an IV curve tracer, the output current produced by the PV panel simulator settles from an initial state to approximately a steady state within a settling time period. This settling time period precedes the measurement time period in which the IV curve tracer measures the current and voltage across the load in the steady state.

The settling time period of the PV panel simulator is equal to or less than the settling time required by the IV curve tracer to make accurate current and voltage measurements of a connected load.

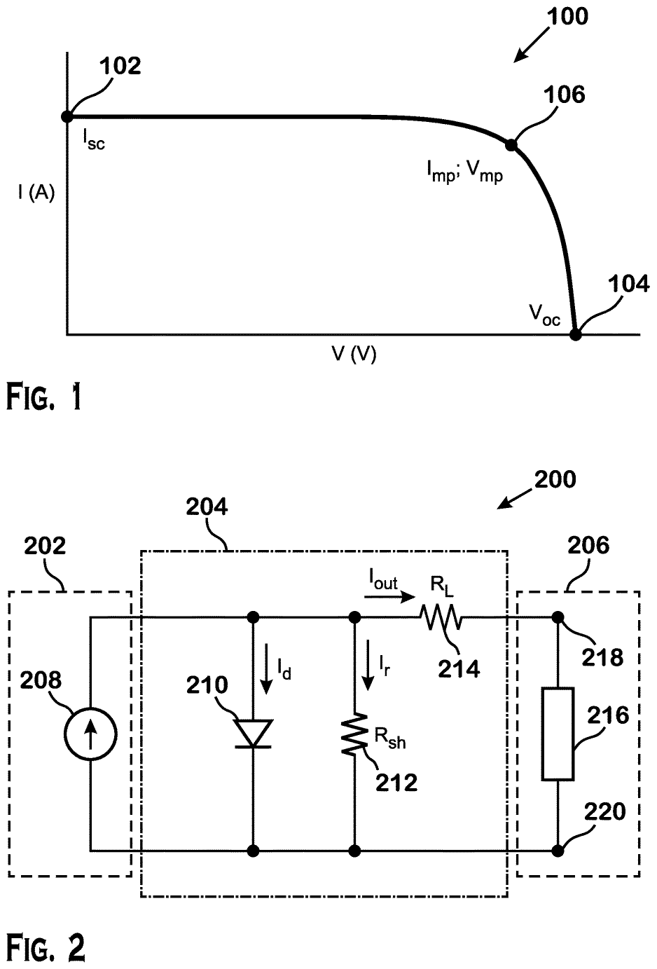

FIG. 1 is a graph that illustrates one example of an IV curve 100 that may be measured by an IV curve tracer connected to an output node of a PV panel. The PV panel may be an actual PV panel or it may be a PV panel simulator as described herein.

The IV curve 100 is comprised of a series of current and voltage measurements made by the IV curve tracer. The series of current and voltage measurements are assembled into a graph as illustrated in FIG. 1. The vertical axis of the graph represents the measured current I (e.g., measured in amperes) and the horizontal axis of the graph represents the measured voltage V (e.g., measured in volts).

Initially, when the IV curve tracer connects a short circuit load to the output node of the PV panel (or PV panel simulator), the measured voltage across the short circuit load is zero and the measured current is a short-circuit current Isc, as indicated at point 102. As loads of increasing impedance are connected to the output node by the IV curve tracer, additional measurements of the current and voltage at the output node are made and included in the graph as shown in FIG. 1. In the example IV curve 100, the output current that flows through the loads initially connected by the IV curve tracer remains relatively constant even though the measured voltage at the output node continues to increase. This continues until the impedance of the loads presented by the IV curve tracer are a high enough that the measured output current begins to drop until a point 104 is reached at which the load presented by the IV curve tracer is an open circuit load. At point 104, the measured current is zero and the measured voltage is at a maximum.

As illustrated in FIG. 1, there is a point 106 at which the PV panel outputs a maximum electrical power. Electrical power determined as a function of the measured current and voltage. The maximum electrical power of the PV panel is determined by a combination of the output current (Imp) and the output voltage (Vmp) at point 106.

An IV curve, such as the IV curve 100, is used to validate the operation of a PV panel. As noted earlier, the PV panel may be tested during manufacture, installation, and/or ongoing operation of the PV panel. IV curve measurements may be compared to an expected “benchmark” IV curve to assess the performance of the PV panel.

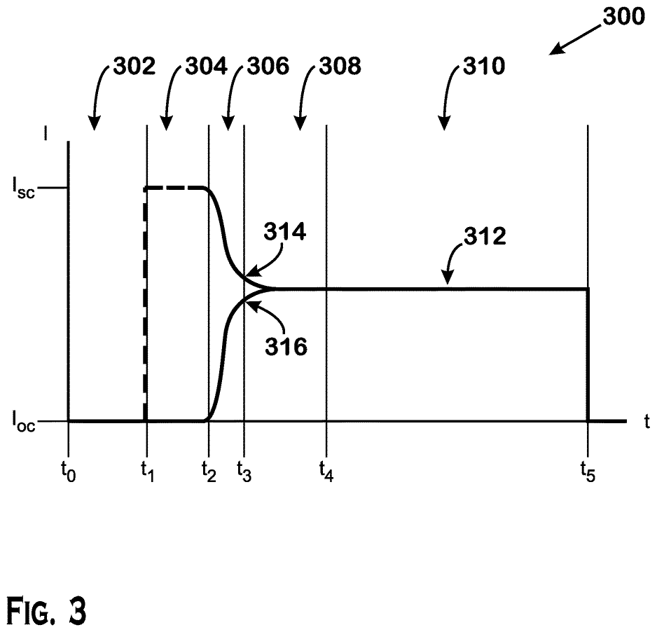

FIG. 2 is a circuit diagram 200 that illustrates a lumped circuit model of a PV panel, which may be an actual PV panel or a PV panel simulator according to the present disclosure. As will be explained below, the PV panel represented by the lumped circuit model in FIG. 2 is connected to a load, which may be a load presented by an IV curve tracer.

In the circuit diagram 200, the lumped circuit model of the PV panel includes portions forming a current source 202, an output circuit 204, and a load 206. The current source 202 includes current source circuitry 208 that produces a source current. The output circuit 204 includes components that model known characteristics of a PV panel. These components are represented by a diode 210 arranged in parallel with a shunt resistor 212 and in series with a loss resistor 214. A portion of the source current generated by the current source circuitry 208 flows through the diode 210 while another portion of the source current flows through the shunt resistor 212. The remaining current (Iout) flows through the loss resistor 214 to an output node 218 of the PV panel. A load 216, e.g. as presented by an IV curve tracer, is connected between the output node 218 and a connection node 220. The output current Iout flows through the load 216. During a measurement time period as described hereafter, the IV curve tracer measures the magnitude of the current Iout and the voltage at the output node 218.

The diode 210 shown in FIG. 2 represents a diode characteristic of the output circuit 204. In an actual implementation of an output circuit of a PV panel simulator 400 as illustrated in FIG. 4, the diode characteristic of the output circuit is achieved using multiple components that are arranged to handle high amounts of current. In other words, the diode 210 in FIG. 2 is symbolic of a diode characteristic and may include more than a single diode element.

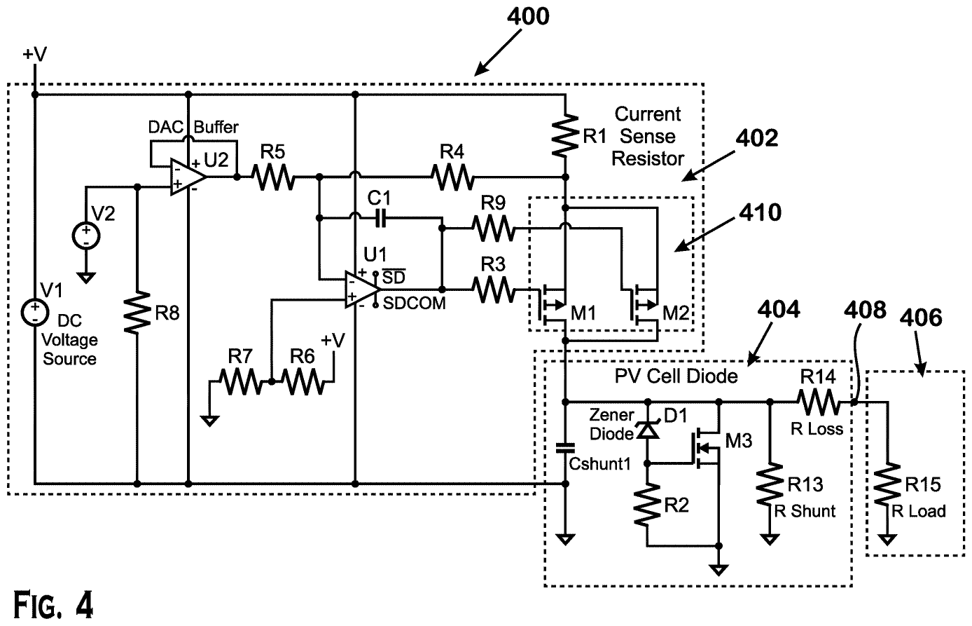

FIG. 3 is a graph that illustrates a timing diagram 300 of an output current produced by a PV panel simulator according to the present disclosure. The timing diagram 300 shows the response of the PV panel simulator to a measurement pulse of an IV curve tracer connected to the PV panel simulator.

IV curve tracers measure fairly large amounts of current and voltage, which may be on the order of 20 A of current at 30V, for example. Such amounts of current and voltage require an IV curve tracer to dissipate a large amount of electrical power in the form of heat. At the same time, it is generally not practical for a field-capable IV curve tracer to have a sophisticated heat dissipation arrangement such as large heatsinks and/or fans. Therefore, a field-capable IV curve tracer generally operates by measuring current and voltage of a PV panel in brief measurement pulses. In order to trace a useful and accurate IV curve, each measurement pulse must have a measurement time period that is long enough for the IV curve tracer to accurately sample the current and voltage at a steady state. In some implementations, the measurement pulses of the IV curve tracer present a series of loads that shift from a short circuit or near-short circuit condition to a load of higher impedance. In other implementations, the measurement pulses of the IV curve tracer presents a series of loads that shift from an open-circuit condition to a load of lower impedance. Regardless, the IV curve tracer measures the current and voltage of the PV panel in measurement pulses which allow the internal components of the IV curve tracer to cool down between measurements.

In the example shown in FIG. 3, the vertical axis of the timing diagram 300 indicates the magnitude of the output current of the PV panel simulator and the horizontal axis indicates time. At a time to, the timing diagram 300 illustrates a time period 302 in which the PV simulator is in an open circuit condition (i.e., the load connected to the PV simulator is very high or completely removed). During this time period 302, the output current Ioc is essentially zero and the internal components of the IV curve tracer are cooling or have cooled.

The measurement pulse begins at time t1 with an initial time period 304 in which the PV simulator is set in an initial state. In some implementations, the initial state is a short circuit state in which the IV curve tracer connects a short circuit load to the PV simulator. The PV simulator quickly produces an output current having a magnitude Isc as shown by the dashed line in FIG. 3. In other implementations, the initial state is an open circuit state in which the PV simulator remains in an open circuit condition.

At time t2, the measurement pulse begins a settling time period 306. The settling time period 306 begins with the IV curve tracer connecting a selected load to the PV simulator. During the settling time period 306, the output current of the PV simulator quickly transitions, or settles, to approximately a steady-state output current 312. In implementations where the initial state of the PV simulator is a short circuit state, the magnitude of the output current of the PV simulator quickly decreases from Isc to a point 314 at which the output current has approximately reached a steady-state magnitude 312. In other implementations where the initial state of the PV simulator is an open circuit state, at time t2 the magnitude of the output current of the PV simulator quickly increases to a point 316 at which the output current has approximately reached the steady-state magnitude 312. In the present disclosure, the output current has approximately reached the steady-state magnitude 312 when the magnitude of the output current is near the steady-state magnitude 312, within for example +/−10% or +/−5% of the steady-state magnitude 312. Notably, and important to the present disclosure, the settling time period 306 concludes before the measurement time period 310 of the IV curve tracer. The measurement time period 310 is the period of time in which the IV curve tracer measures the magnitude of the output current and voltage at the output node in a steady state condition.

In some cases, the measurement pulse includes a stabilization time period 308 in which the magnitude of the output current of the PV simulator stabilizes at or very near the steady-state magnitude 312. Thus, after the settling time period, the magnitude of the output current reaches the steady state during a stabilization time period, which in various implementations may be in a range of 150-250 μsec. In at least one implementation, the stabilization time period is approximately 200 usec.

The measurement time period 310 thereafter begins at time t4 and ends at time t5. During the measurement time period 310, the IV curve tracer measures the magnitude of the output current and voltage at the output node in a steady state condition.

At time t5, the measurement time period 310 ends, and the IV curve tracer returns the PV simulator to an open circuit condition by connecting a very high impedance load or removing the load from the PV simulator altogether. After time t5, with the PV simulator in the open circuit condition, the timing diagram 300 returns to time t0 for the next measurement pulse. The timing diagram 310 is repeated for each measurement point in the IV curve until the IV curve is completed, e.g., as illustrated in FIG. 1.

FIG. 4 is a circuit diagram illustrating one example of a PV panel simulator 400 configured according to the present disclosure and connected to a load 406 of an IV curve tracer.

In the example shown, the PV panel simulator 400 includes a high-side linear current source 402 and an output circuit 404. The high-side linear current source 402 is configured to generate a source current that is delivered to the output circuit 404. The high-side linear current source 402 includes, at least in part, a voltage source V1 and a feedback loop that include a number of circuit elements. The feedback loop is implemented, in part, with an operational amplifier U1 that controls the source current generated by the high-side linear current source 402. The source current is generated in response to a reference signal received by the operational amplifier U1 from a controller V2 via a unity gain buffer U2 and a feedback signal received via the feedback loop.

The output circuit 404 is configured to receive the source current from the high-side linear current source 402 and produce an output current at an output node 408. The output circuit 404 includes one or more components having configurable electrical parameters that, in combination, simulate electrical characteristics of a PV panel.

As described herein, in response to connection of a load, e.g., R15 of an IV curve tracer, to the output node 408, the output current delivered to the load R15 has a magnitude that settles from an initial state to approximately a steady state within a settling time period. The PV panel simulator 400 is configured, as described herein, with settling time period that precedes a measurement time period during which the IV curve tracer can measure the magnitude of the output current and voltage at the output node 408 in the steady state. The measurement time period of the IV curve tracer is based on a timing of a measurement pulse (e.g., as shown in FIG. 3) during which the IV curve tracer measures the magnitude of the output current and the voltage at the output node 408.

The controller V2 in the high-side linear current source 402 may be a digital-to-analog converter (DAC). The operational amplifier U1 operates in response to a reference signal received from the DAC and the feedback voltage received via the feedback loop to control the source current produced by the high-side linear current source 402.

In the example shown in FIG. 4, the feedback loop includes a current sense resistor R1 that is coupled between the voltage source V1 and a transistor network 410. The feedback voltage provided to the operational amplifier U1 via resistor R4 depends at least in part on the voltage across the current sense resistor R1. The operational amplifier U1 is configured to control operation of the transistor network 410 such that the source current delivered to the output circuit 404 is generated from current flowing through the current sense resistor R1 and the transistor network 410. Because the PV panel simulator 400 is implemented using a high-side current source 402, the current source 402 acts as a current source rather than a current sink.

In the example shown in FIG. 4, the transistor network 410 is comprised of multiple transistors, e.g., positive metal oxide semiconductor (PMOS) transistors M1 and M2, arranged in parallel and having respective gate terminals coupled to an output of the operational amplifier U1. The output of the operational amplifier Ul thus controls the electrical impedance of the transistor network 410. As can be seen, the operational amplifier Ul is configured to control operation of the transistor network 410 based on a combination of the reference signal from the controller (DAC) V2 and the voltage across the current sense resistor R1.

In the example shown in FIG. 4, the feedback voltage is coupled to an inverting input of the operational amplifier U1. Separately, a constant reference voltage obtained from a voltage divider comprised of resistors R6 and R7 is coupled to a non-inverting input of the operational amplifier U1. The operational amplifier U1 is configured to control the source current based on the received feedback voltage so as to minimize a voltage difference between the inverting and non-inverting inputs. Based on a voltage difference between the DAC and the current sense resistor, the operational amplifier U1 simultaneously drives the parallel PMOS transistors M1 and M2, which act as a single device.

The operational amplifier U1 thus controls the transistor network 410 (in this case, the two PMOS devices M1, M2) so that the voltage divider comprised of R1, R4, and R5 arranged with the controller (DAC) V2 maintains a feedback voltage at the inverting (−) input of the operational amplifier Ul that is the same as the constant voltage provided by the voltage divider R6 and R7 at the non-inverting input (+). With a feedback topology as shown, the operational amplifier U1 operates to maintain (as best possible) a zero-voltage difference between the inverting and non-inverting inputs, so as to maintain the linear operation of the high-side linear current source 402.

The reference signal (i.e., output voltage) of the controller (DAC) V2 essentially sets the amount of the source current that is produced by the high-side linear current source 402. If, for example, the DAC is set to output a reference signal of zero, then the voltage divider of R1, R4, and R5 (with a voltage drop across the current sense resistor R1 being negligible) will produce a feedback voltage at the inverting input of the operational amplifier U1 that matches the constant voltage developed by the voltage divider of R6 and R7 at the non-inverting input. If, by way of example, the DAC instead outputs a reference signal of 5V and assuming the current sense resistor R1 is 0.1 ohm, the high-side linear current source 402 will need a voltage drop of 2 volts across the current sense resistor R1 in order to maintain the same voltage input at the non-inverting and inverting inputs of the operational amplifier U1. Accordingly, the operational amplifier U1 will produce an output that drives the gates of the PMOS transistors M1 and M2 to allow a source current of 20 amps to flow through them, thereby achieving a 2 volt drop across the current sense resistor R1 (20 A*0.1 ohm=2 volts). In this example, the high-side linear current source 402 is able to quickly generate a desired source current of 20 amps.

As noted earlier, the output circuit 404 includes one or more electrical components that provide the output circuit 404 with a diode characteristic. Such electrical components in the example shown in FIG. 4 include a Zener diode D1 arranged in parallel with a PMOS transistor M3 in series with a resistor R2 to ground. The diode characteristic in the output circuit 404 is arranged in parallel with a shunt resistor R13 and in series with a loss resistor R14. The loss resistor R14 is coupled to the output node 408. The one or more electrical components D1, M3, R2 providing the diode characteristic, the shunt resistor R13, and/or the loss resistor R14 are user configurable. A user can thus configure the electrical components to simulate different electrical characteristics of different PV panels. The output circuit 404 may further include a configurable shunt capacitor Cshunt1 arranged in parallel with the one or more electrical components D1, M3, R2 that provide the diode characteristic.

While there are PV panel simulators in the market designed for testing inverters that boost the output voltage of a PV panel, such PV panel simulators are incapable of calibrating IV curve tracers. The output of such PV panel simulators are not able to respond quickly enough to operate correctly with short duration measurement pulses of a field-capable IV curve tracer. Typical DC bench supplies have a similar deficiency. This is because DC bench supplies generally sacrifice response time in favor of stability.

In contrast to known PV panel simulators, the PV panel simulator described herein is able settle its output current and voltage in a short settling time period that concludes before (i.e., precedes) the measurement time period of the IV curve tracer measurement pulse. The particular settling time in a PV panel simulator of the present disclosure depends largely on the selection of components such as the PMOS transistors and on the shunt capacitance used. In some implementations, the settling time period may be in a range of 2-100 μsec. In some implementations, the settling time period may be as short as approximately 2 μsec (+/−1 μsec). In other implementations, the settling time period may be approximately 100 μsec, or more. Implementations of the PV panel simulator described herein tolerate having the output node 408 short-circuited and open-circuited without damage or disturbance to the PV panel simulator or the IV curve tracer. The PV panel simulator described herein is able to realistically simulate the electrical characteristics of an actual solar panel.

Implementations of the PV panel simulator described herein are also user-programmable (e.g., using knobs or other physical or logical configuration tools) to allow a user to vary parameters such as output current, output voltage, series and shunt resistance, and shunt capacitance, to simulate a variety of PV panels under different environmental and load conditions.

By quickly producing an output current and voltage within a settling time period that precedes the measurement time period of the IV curve tracer, the PV panel simulator enables the IV curve tracer to measure an IV curve and that the measurements accurately represent the operation of the IV curve tracer. The IV curve thus generated by the PV panel simulator can be used for calibrating the IV curve tracer.

Calibration is a process of comparing the reading or performance of a measurement tool, such as an IV curve tracer, with a reference standard of known accuracy. Calibration of the IV curve tracer may be performed by comparing the IV curve measured by the IV curve tracer with an expected IV curve (“known standard”). The known standard in this case is based on specifications of the PV panel being simulated by the PV panel simulator, operating under known conditions. If the IV curve measured by the IV curve tracer differs from the known standard, one or more calibration corrections may be determined and applied to the IV curve tracer to cause the IV curve tracer to output a measured IV curve that matches the known standard under the same operating conditions as previously tested. The one or more calibration corrections may be determined and applied to the IV curve tracer by the PV panel simulator or by other external calibration equipment in communication with the IV curve tracer.

In some implementations, the PV panel simulator may thus comprise one or more processors that are configured to compare an IV curve measured by the IV curve tracer with an expected IV curve, and determine one or more calibration corrections to be applied to the IV curve tracer based on a difference between the IV curve produced by the IV curve tracer and the expected IV curve. The expected IV curve may be a known standard that is based on specifications of the PV panel being simulated by the PV panel simulator, operating under known conditions. In some implementations, the IV curve measured by the IV curve tracer is communicated to external calibration equipment that is configured to compare the IV curve produced by the IV curve tracer with the expected IV curve and determine and apply the one or more calibration corrections. In some implementations, the PV panel simulator is configured to determine and apply the one or more calibration corrections to the IV curve tracer.

As evident from the foregoing description, the present disclosure encompasses methods for calibration of a measurement tool (e.g., for IV curve tracing) as described herein. In at least one implementation, a method for calibration of a measurement tool for IV curve tracing includes configuring a PV panel simulation system as described herein to simulate a PV panel; connecting the measurement tool to the PV panel simulation system and measuring an IV curve based on voltage and current output by the PV panel simulation system; communicating the IV curve to calibration equipment that is configured to compare the IV curve with an expected IV curve for the PV panel being simulated; and determining one or more calibration corrections for the measurement tool based on a comparison of the IV curve with the expected IV curve. The method may further include applying the one or more calibration corrections to the measurement tool.

An aspect of the PV panel simulator described herein is that it includes a linear implementation of the high-side current source which, as configured herein, quickly produces a source current without the use of a switching converter. Such implementations allow the PV panel simulator to have a negligible output capacitance, allowing a sufficiently fast response to transients caused by different loads being connected to the PV panel simulator.

The various embodiments described above can be combined to provide yet further embodiments. These and other changes can be made in light of the above-detailed description. In general, in the following claims, the terms used should not be construed to limit the claims to the specific embodiments disclosed in the specification and claims, but should be construed to include all possible embodiments along with the full scope of equivalents to which such claims are entitled.

1. A photovoltaic (PV) panel simulation system, comprising:
a high-side linear current source configured to generate a source current, wherein the high-side linear current source is comprised of a voltage source and a feedback loop, the feedback loop being implemented with an operational amplifier that controls the source current in response to a reference signal received from a controller and a feedback signal received via the feedback loop; and
an output circuit configured to receive the source current and produce an output current, the output circuit including one or more configurable electrical parameters which, in combination, simulate electrical characteristics of a photovoltaic (PV) panel,
wherein, in response to connection of a load of a current-voltage (IV) curve tracer to the output circuit, the output current is produced at an output node at a magnitude that settles from an initial state to approximately a steady state within a settling time period, and
wherein the settling time period precedes a measurement time period during which the IV curve tracer can measure the magnitude of the output current and voltage across the load in the steady state.

2. The PV panel simulation system of claim 1, wherein the measurement time period is based on a timing of a measurement pulse during which the IV curve tracer measures the magnitude of the output current and voltage at an output of the PV panel simulator.

3. The PV panel simulation system of claim 1, wherein the settling time period is in a range of 2-100 μsec.

4. The PV panel simulation system of claim 3, wherein the settling time period is approximately 2 μsec.

5. The PV panel simulation system of claim 1, wherein, after the settling time period, the magnitude of the output current reaches the steady state during a stabilization time period in a range of 150-250 μsec.

6. The PV panel simulation system of claim 5, wherein the stabilization time period is approximately 200 μsec.

7. The PV panel simulation system of claim 1, wherein the controller includes a digital-to-analog converter (DAC), and the operational amplifier controls the source current in response to a reference signal received from the DAC and the feedback signal received via the feedback loop.

8. The PV panel simulation system of claim 7, wherein the feedback loop includes a current sense resistor coupled between the voltage source and a transistor network, and the feedback signal depends at least in part on a voltage across the current sense resistor.

9. The PV panel simulation system of claim 8, wherein the operational amplifier is configured to control operation of the transistor network such that the source current is generated from current flowing through the current sense resistor and the transistor network.

10. The PV panel simulation system of claim 8, wherein the transistor network is comprised of multiple positive metal oxide semiconductor (PMOS) transistors arranged in parallel, having respective gate terminals coupled to an output of the operational amplifier that controls an electrical impedance of the transistor network.

11. The PV panel simulation system of claim 8, wherein the operational amplifier is configured to control an operation of the transistor network based on a combination of the reference signal from the DAC and the voltage across the current sense resistor.

12. The PV panel simulation system of claim 1, wherein:
the feedback voltage is coupled to an inverting input of the operational amplifier;
a reference voltage is coupled to a non-inverting input of the operational amplifier; and
the operational amplifier is configured to control the source current by minimizing a voltage difference between its inverting and non-inverting inputs.

13. The PV panel simulation system of claim 1, wherein the output circuit includes one or more electrical components providing a diode characteristic arranged in parallel with a shunt resistor and in series with a loss resistor, wherein the loss resistor is coupled to the output node of the PV panel simulator.

14. The PV panel simulation system of claim 13, wherein the one or more electrical components providing the diode characteristic, the shunt resistor, and/or the loss resistor are user configurable to simulate different electrical characteristics of different PV panels.

15. The PV panel simulation system of claim 14, wherein the output circuit further includes a configurable shunt capacitor in parallel with the one or more electrical components providing the diode characteristic.

16. The PV panel simulation system of claim 1, further comprising one or more processors configured to compare an IV curve measured by the IV curve tracer with an expected IV curve, and determine one or more calibration corrections to be applied to the IV curve tracer based on a difference between the IV curve measured by the IV curve tracer and the expected IV curve.

17. The PV panel simulation system of claim 16, wherein the expected IV curve is a known standard based on specifications of the PV panel being simulated by the PV panel simulator, operating under known conditions.

18. The PV panel simulation system of claim 16, wherein the PV panel simulator is configured to determine and apply the one or more calibration corrections to the IV curve tracer.

19. A method for calibration of a measurement tool for IV curve tracing, comprising:
configuring a PV panel simulation system according to claim 1 to simulate a PV panel;
connecting the measurement tool to the PV panel simulation system and measuring an IV curve based on voltage and current output by the PV panel simulation system;
communicating the IV curve to calibration equipment that is configured to compare the IV curve with an expected IV curve for the PV panel being simulated; and
determining one or more calibration corrections for the measurement tool based on a comparison of the IV curve with the expected IV curve.

20. The method of claim 19, further comprising applying the one or more calibration corrections to the measurement tool.
